(19) United States
(12) Patent Application Publication
(10) Pub. No.: US 2024/0096948 A1
(43) Pub. Date: Mar. 21, 2024

(54) STRUCTURE HAVING ENHANCED GATE RESISTANCE

(71) Applicant: International Business Machines Corporation, Armonk, NY (US)

(72) Inventor: Terence Hook, Jericho Center, VT (US)

(21) Appl. No.: 17/945,275

(22) Filed: Sep. 15, 2022

(51) Int. Cl. H01L 29/06; H01L 29/423; H01L 29/775; H01L 29/786

(52) U.S. Cl. CPC H01L 29/0673; H01L 29/42392; H01L 29/775; H01L 29/78696

(57) ABSTRACT

Semiconductor structures such as, for example, stacked nanosheet devices, having enhanced gate resistance are provided. The enhanced gate resistance is obtained by providing a shunting material pillar in the structure and along a sidewall (or opposing sidewalls) of at least one gate structure. The shunting material pillar has a resistivity that is lower than a resistivity of the gate structure that it is laterally adjacent to.

### BACKGROUND

The present application relates to semiconductor technology, and more particularly to semiconductor structures having enhanced gate resistance.

A metal oxide semiconductor field effect transistor (MOSFET) is a transistor used for switching electronic signals. The MOSFET has a source region, a drain region, and a metal gate electrode. The metal gate electrode is electrically insulated from the main semiconductor n-channel or p-channel by a thin layer of insulating material, for example, silicon dioxide or high dielectric constant (high-k) dielectrics. The metal gate electrode is relatively tall and narrow which makes the input resistance of the MOSFET relatively high. The gate voltage controls whether the path from drain to source is an open circuit (“off”) or a resistive path (“on”). The threshold voltage of the transistor is at least partly determined by the work function of the metal gate, and the conductivity of that metal may also limit the gate resistance. The charging of the gate capacitance can limit the frequency response of the transistor.

N-type field effect transistors (nFETs) and p-type field effect transistors (pFETs) are two types of complementary MOSFETs. The nFET uses electrons as the current carriers and with n-doped source and drain junctions. The pFET uses holes as the current carriers and with p-doped source and drain junctions. In contemporary semiconductor device fabrication processes, a large number of nFETs and pFETs are fabricated on a single wafer.

As semiconductor devices scale to smaller dimensions, non-planar devices including gate-all-around devices such provide advantages. For example, gate-all-around devices provide area efficiency. Gate-all-around devices further provide, for example, increased drive current within a given layout area. Stacking devices offers even more density, but as the gate metal is taller, gate resistance is of greater significance.

### SUMMARY

The present application provides semiconductor structures such as, for example, stacked nanosheet devices, having enhanced gate resistance. The enhanced gate resistance is obtained by providing a shunting material pillar in the structure and along a sidewall (or on opposing sidewalls) of at least one gate structure. The shunting material pillar has a resistivity that is lower than a resistivity of the gate structure that it is laterally adjacent to.

In one aspect of the present application, a semiconductor structure is provided. In one embodiment, the semiconductor structure includes a first field effect transistor including a first gate structure, wherein the first gate structure has a first sidewall and a second sidewall opposite the first sidewall. The structure further includes a second field effect transistor stacked vertically on top of the first field effect transistor and including a second gate structure, wherein the second gate structure has a first sidewall and a second sidewall opposite the first sidewall, and wherein the first sidewall of the second gate structure is vertically aligned with the first sidewall of the first gate structure and the second sidewall of the second gate structure is vertically aligned with the second sidewall of the first gate structure. The structure even further includes a shunting material pillar located along at least one of the first sidewall of both the first gate structure and the second gate structure or the second sidewall of both the first gate structure and the second gate structure.

In another embodiment of the present application, the semiconductor structure incudes a first field effect transistor located in a first device region and including a first gate structure. The structure further includes a second field effect transistor located in a second device region that is laterally adjacent to the first device region and includes a second gate structure. The structure yet further includes a first shunting material pillar located along at least one sidewall of the first gate structure, and a second shunting material pillar located along at least one sidewall of the second gate structure.

### BRIEF DESCRIPTION OF THE DRAWINGS

FIG. 1 is a cross sectional view of an exemplary semiconductor structure, i.e., stacked nanosheet device, in accordance with the present application.

FIG. 2A is a top down view of an exemplary semiconductor structure in accordance with an embodiment of the present application.

FIG. 2B is a top down view of a semiconductor structure in accordance with another embodiment of the present application.

FIG. 3 is a cross sectional view of another exemplary semiconductor structure, i.e., non-stacked nanosheet device in accordance with the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Although the present application describes and illustrates first and second field effect transistors (FETs) as both being nanosheet-containing FET devices, i.e., devices in which a plurality of vertically stacked semiconductor nano sheets are employed as a channel material and a gate structure wraps around each of the semiconductor nanosheets, the present application contemplates embodiments in which FinFET devices, nanowire devices, planar FET devices or any combination thereof, i.e., nanosheet-containing FET devices and FinFET devices, are employed. In the present application, a FET includes at least a gate dielectric material layer contacting a channel material, and a gate structure located on the gate dielectric material layer.

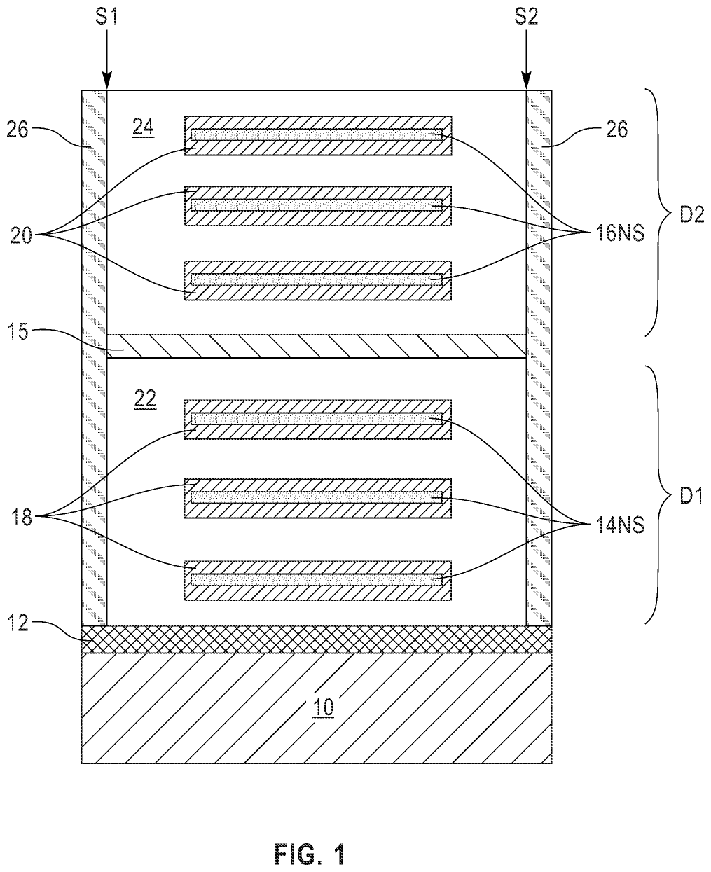

Referring first to FIG. 1, there is illustrated an exemplary semiconductor structure in accordance with the present application. The exemplary semiconductor structure illustrated in FIG. 1 includes a first field effect transistor including a first gate structure 22, wherein the first gate structure 22 has a first sidewall S1 and a second sidewall S2 opposite the first sidewall. The structure further includes a second field effect transistor stacked vertically on top of the first field effect transistor and including a second gate structure 24, wherein the second gate structure 24 has a first sidewall S1 and a second sidewall S2 opposite the first sidewall S1, and wherein the first sidewall S1 of the second gate structure 24 is vertically aligned with the first sidewall S1 of the first gate structure 22 and the second sidewall S2 of the second gate structure 24 is vertically aligned with the second sidewall S2 of the first gate structure 22. The structure even further includes a shunting material pillar 26 located along at least one of the first sidewall S1 of both the first gate structure 22 and the second gate structure 24 or the second sidewall S2 of both the first gate structure 22 and the second gate structure 24. The illustrated embodiment shows a shunting material pillar 26 located along the first sidewall S1 of both the first gate structure 22 and the second gate structure 24, and along the second sidewall S2 of both the first gate structure 22 and the second gate structure 24. In other embodiments, the shunting material pillar 26 can be present on the first sidewall S1, yet absent from the second sidewall S2, or it can be present on the second sidewall S2, but absent from the first sidewall S1.

The exemplary structure shown in FIG. 1 further illustrates that the first field effect transistor including the first gate structure 22 is located above a bottom dielectric isolation layer 12 that is present on a semiconductor substrate 10. In such an embodiment, the first gate structure 22 can be in direct contact with the bottom dielectric isolation layer 12. In other embodiments (not shown, but readily derivable from the illustrated structure shown in FIG. 1), the bottom dielectric isolation layer 12 can be omitted and, in such embodiments, the first gate structure 22 can be in direct contact with the semiconductor substrate 10.

In the present application and as is illustrated in FIG. 1, the first field effect transistor including the first gate structure 22 is located in a first device region D1, and the second field effect transistor including the second gate structure 24 is located in a second device region D2. In embodiments, and as is shown, D1 can be spaced apart from D2 by a device separating dielectric material layer 15. In some embodiments, the device separating dielectric material layer 15 can be omitted.

In some embodiments of the present application the first field effect transistor is a first conductivity type and the second field effect transistor is of second conductivity type, and the second conductivity type is of a different conductivity than the first conductivity type. In a first example, the first conductivity type is n-type, and the second conductivity type is p-type, and in a second example, the first conductivity type is p-type, and the second conductivity type is n-type. In yet other embodiments of the present application, the first field effect transistor is a first conductivity type and the second field effect transistor is of second conductivity type, and the second conductivity type is of a same conductivity as the first conductivity type. Thus, the present application contemplates a pFET stacked on top of an nFET, an nFET stacked on top of a pFET, an nFET stacked over another nFET, or a pFET stacked over another pFET. Also, the present application contemplates embodiments in which additional device regions including additional FETs are stacked above the second device region D2.

In the illustrated embodiment shown in FIG. 1, the first gate structure 22 wraps around each first semiconductor channel material nanosheet 14NS of a plurality of first semiconductor channel material nanosheets, and the second gate structure 24 wraps around each second semiconductor channel material nanosheet 16NS of a plurality of second semiconductor channel material nanosheets. As is illustrated, each first semiconductor channel material nanosheet 14NS is present in a first vertical nanosheet containing stack, while each second semiconductor channel material nanosheet 16NS is present in a second vertical nanosheet containing stack. In the illustrated embodiment, the second vertical nanosheet containing stack is present directly above the first vertical nanosheet containing stack.

The exemplary structure shown in FIG. 1 illustrates first and second semiconductor material channel nanosheets 14NS and 16NS of the first and second device regions, respectively, as the same width as one another and each composed of three spaced apart nanosheets. In other embodiments the width and number of nanosheets in the first device region may be more or less than in the second device region, depending on the desired electrical characteristics.

As is further illustrated in FIG. 1, the structure further includes a first gate dielectric material layer 18 separating the first gate structure 22 from each first semiconductor channel material nanosheet 14NS of the plurality of first semiconductor channel material nanosheets, and a second gate dielectric material layer 20 separating the second gate structure 24 from each second semiconductor channel material nanosheet 16NS of the plurality of second semiconductor channel material nanosheets.

Although not shown, the first field effect transistor would include first source/drain regions, and the second field effect transistor would include second source/drain regions. In FIG. 1, the first and second source/drain regions would be present out of the plane and into the plane of the drawing sheet containing FIG. 1.

Although not shown (but can be readily derived from FIG. 1), the present application contemplates at least one other stacked field effect transistor device located laterally adjacent to first field effect transistor and the second field effect transistor, wherein the at least one other stacked field effect transistor device is devoid of a shunting material pillar.

The various components/elements mentioned above and as illustrated in FIG. 1 are now described in greater detail. The semiconductor substrate 10 is composed of a semiconductor material having semiconducting properties. Examples of semiconductor materials that can be used to provide the semiconductor substrate include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor substrate 10 can be composed of one or more of these semiconductor materials. In one embodiment, a bulk substrate is used as semiconductor substrate 10. The term “bulk substrate” denotes a substrate that is entirely composed of one or more semiconductor materials. An example of a bulk semiconductor substrate is a Si substrate. In some embodiments, the semiconductor substrate 10 is a semiconductor-on-insulator (all) substrate. The SOI substrate has a bottom handle layer (which can be composed of one of the semiconductor materials), a buried dielectric layer (which can be composed of silicon dioxide and/or boron nitride) and a top semiconductor layer (which can be composed of one of the semiconductor materials mentioned above). An example of a SOI substrate is a substrate composed of Si/silicon dioxide/Si.

The bottom dielectric isolation layer 12 is composed of a dielectric material including, but are not limited to, SiO₂, SiN, SiBCN, SiOCN or SiOC. The bottom dielectric isolation layer 12 can have a thickness from 5 nm to 50 nm; although other thicknesses for the bottom dielectric isolation layer 12 are contemplated and can be employed as the thickness of the bottom dielectric isolation layer 12. In some embodiments and as mentioned above, the bottom dielectric isolation layer 12 can be omitted.

Each first semiconductor channel material nanosheet 14NS of the plurality of first semiconductor channel material nanosheets is composed of a first semiconductor material. The first semiconductor material includes one of the semiconductor materials mentioned above for the semiconductor substrate. In some examples, the first semiconductor material that provides each first semiconductor channel material nanosheet 14NS is composed of silicon or a silicon germanium alloy. In some embodiments, the first semiconductor material that provides each first semiconductor channel material nanosheet 14NS is capable of providing high channel mobility for an nFET. In other embodiments, the first semiconductor material that provides each first semiconductor channel material nanosheet 14NS is capable of providing high channel mobility for a pFET.

Each second semiconductor channel material nano sheet 16NS of the plurality of second semiconductor channel material nanosheets is composed of a second semiconductor material. The second semiconductor material, which includes one of the semiconductor materials mentioned above for the semiconductor substrate, can be compositionally the same as, or compositionally different from, the first semiconductor material that provides each first semiconductor channel material nanosheet 14NS. In some examples, the second semiconductor material that provides each second semiconductor channel material nanosheet 16NS is composed of silicon or a silicon germanium alloy. In some embodiments, the second semiconductor material that provides each second semiconductor channel material nanosheet 16NS is capable of providing high channel mobility for an nFET. In other embodiments, the second semiconductor material that provides each second semiconductor channel material nanosheet 16NS is capable of providing high channel mobility for a pFET. In one exemplary embodiment, the first semiconductor material is capable of providing high channel mobility for an nFET, while the second semiconductor material is capable of providing high channel mobility for an nFET. In another exemplary embodiment, the first semiconductor material is capable of providing high channel mobility for a pFET, while the second semiconductor material is capable of providing high channel mobility for a pFET.

Each first semiconductor channel material nanosheet 14NS has a first width and a first vertical height. In one example, the first width is from 10 nm to 100 nm, and the first vertical height is from 4 nm to 20 nm. Each second semiconductor channel material nanosheet 16NS has a second width and a second vertical height which are typically in the ranges mentioned above for the first width and first vertical height, respectively. The length of the first and second semiconductor channel material nanosheets 14NS and 16NS are typically the same. As mentioned above, the widths of the first and second semiconductor channel material nanosheets 14NS and 16NS need not be the same value.

The first gate dielectric material layer 18 is composed of a first gate dielectric material such as, for example silicon oxide, or a dielectric material having a dielectric constant greater than 4.0 (such dielectric materials can be referred to as a high-k gate dielectric material). Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric material can further include dopants such as lanthanum (La), aluminum (Al) and/or magnesium (Mg).

The second gate dielectric material layer 20 is composed of a second gate dielectric material including silicon oxide or a high-k dielectric material as mentioned above for the first gate dielectric material. The second gate dielectric material can be compositionally the same as, or compositionally different from, the first gate dielectric material.

The first gate structure 22 includes at least a first work function metal (WFM). The first WFM can be used to set a threshold voltage of the FET to a desired value. In some embodiments, the first WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the first WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof.

The second gate structure 24 includes a second WFM. The second WFM metal includes one of the WFMs mentioned above for the first WFM. The second WFM can be compositionally the same as, or compositionally different from, the first WFM. In one example, the first WFM includes an n-type work function metal, and the second WFM includes a p-type work function metal. In another example, the first WFM includes a p-type work function metal, and the second WFM includes n-type work function metal.

In some embodiments, the first gate structure 22 and/or the second gate structure 24 includes a gate electrode material as well as the WFM. When present, the gate electrode material is located adjacent to the WFM and it can be composed of an electrically conductive metal-containing material including, but not limited to, tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaC_{X}), titanium carbide (TiC), titanium aluminum carbide, tungsten silicide (WSi₂), tungsten nitride (WN), ruthenium oxide (RuO₂), cobalt silicide, or nickel silicide.

The device separating dielectric material layer 15 that can be present between D1 and D2 includes any dielectric material such as, for example, silicon dioxide, silicon nitride or a combination thereof. The device separating dielectric material layer 15 can have a thickness from 20 nm to 100 nm; although other thicknesses are contemplated and can be used as the thickness of the device separating dielectric material layer.

The shunting material pillar 26 has a resistivity that is lower than a resistivity of both the first gate structure 22 and the second gate structure 24. In one example, the specific conductivity of the shunting material pillar 26 is 5-20 times that of the specific conductivity of both the first gate structure 22 and the second gate structure 24. The shunting material pillar can be composed of cobalt, tungsten, or ruthenium, for example. The shunting material pillar 26 provides enhanced gate resistance to the stacked device shown in FIG. 1, and the presence of the same can also improve the frequency response of the stacked device illustrated in FIG. 1.

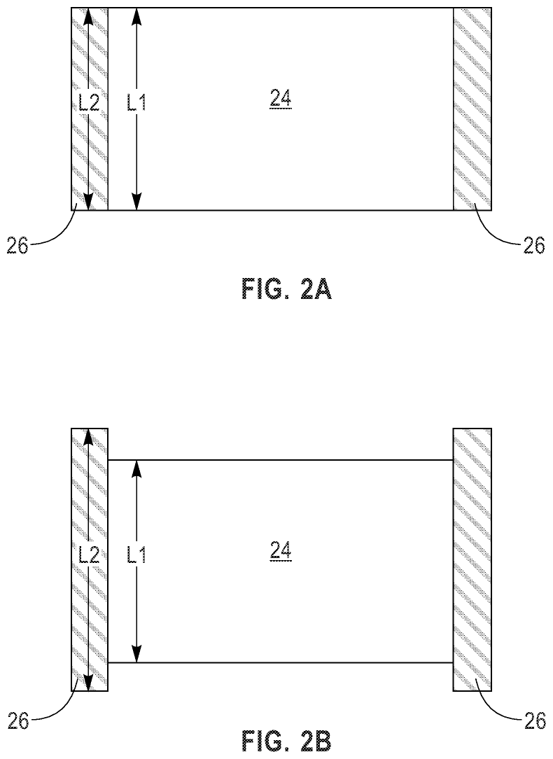

Referring now to FIGS. 2A and 2B, there are illustrated exemplary semiconductor structures similar to the exemplary structure shown in FIG. 1. Notably, FIG. 2A shows an embodiment in which the shunting material pillar 26 has a length L2 that is equal to a length L1 of both the first gate structure 22 (not shown but beneath the second gate structure 14) and the second gate structure 24. Notably, FIG. 2B shows an embodiment in which the shunting material pillar 26 has a length L2 that greater than a length L1 of both the first gate structure 22 and the second gate structure 24. In some embodiments, and when present on both the first sidewall Si and the second sidewall S2 it is possible to have a case in which the shunting material pillar along the first sidewall Si has a different length than the shunting material pillar 26 along the second sidewall S2.

The exemplary structure shown in FIG. 1 minus the shunting material pillar 26 can be formed utilizing well known nanosheet device stacking processing techniques. So as not to obscure the method used in providing the shunting material pillar 26, the processing details used in forming the stacked nanosheet device shown in FIG. 1 will not be described herein. The method of forming the shunting material pillar 26 is now described. Notably, and after forming the second field transistor including the second gate structure 24, a mask can be formed which includes at least one opening that physically exposes at least one end of the second gate structure and the underlying first gate structure. The opening can be aligned with the exposed end portion of the second gate structure 24 or it can extend beyond the exposed end portion of the second gate structure 24. An etch is then performed that removes at least the physically exposed end portion of the second gate structure 24 as well as the underlying first gate structure 22 providing the first sidewall S1 and/or second sidewall S2 mentioned above. This etch forms a space, or gap along S1 and/or S2. The mask is then typically removed and a shunting material is formed into each space or gap by a deposition process such as, for example, chemical vapor deposition (CVD), plasma enhanced chemical vapor deposition (PECVD), physical vapor deposition (PVD), atomic layer deposition (ALD), sputtering or plating. After the deposition process, a planarization process such as, for example, chemical mechanical polishing (CMP) can be used to remove any shunting material that is formed outside the space or gap and on top of the second gate structure 24. The shunting material that remains in the spacer or gap provides the shunting material pillar 26 of the present application. The shunting material pillar 26 typically has a topmost surface that is coplanar with a topmost surface of the second gate structure 24. The shunting material pillar 26 can land on either the bottom dielectric isolation layer 12 or the semiconductor substrate 10. The mask spacing from the active gate should be arranged such that the shunting material does not adversely affect the threshold voltage of the transistors.

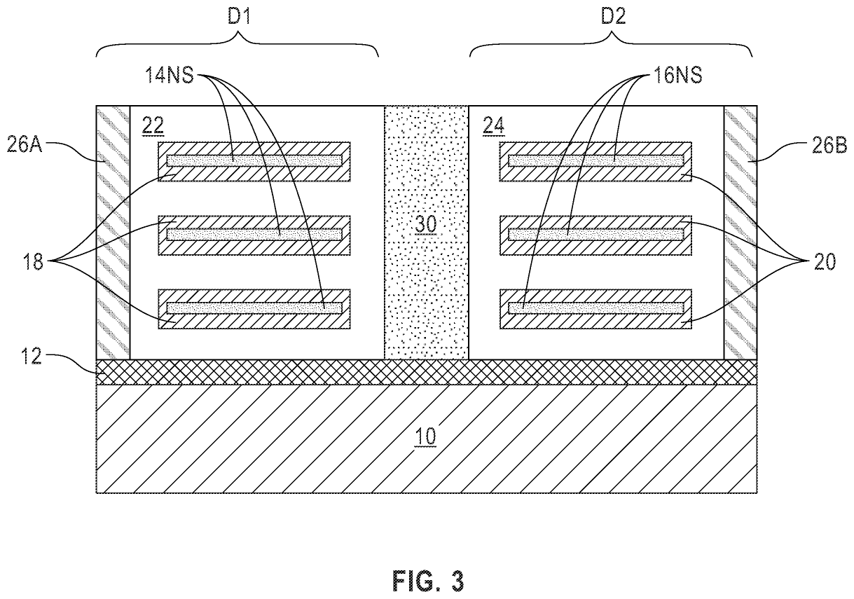

Referring now to FIG. 3, there is illustrated another exemplary semiconductor structure, i.e., non-stacked nanosheet device in accordance with the present application. This illustrated semiconductor structure incudes a first field effect transistor located in a first device region D1 and including a first gate structure 22. The structure further includes a second field effect transistor located in a second device region D2 that is laterally adjacent to the first device region D1 and including a second gate structure 24. The structure yet further includes a first shunting material pillar 26A located along at least one sidewall of the first gate structure, and a second shunting material pillar 26B located along at least one sidewall of the second gate structure 24. In the illustrated embodiment, each of the first and second shunting material pillars 26A, 26B, respectively, is formed along a single sidewall of an appropriate gate structure. In other embodiments, each of the first and second shunting material pillars 26A, 26B is formed along opposing sidewalls of the appropriate gate structure. In yet other embodiments, the first shunting material pillar 26A is formed along opposing sidewalls of the first gate electrode 22, while the second shunting material pillar 24B is formed along only one of the sidewalls of the second gate electrode 24. In yet other embodiments, the second shunting material pillar 26B is formed along opposing sidewalls of the second gate electrode 24, while the first shunting material pillar 26A is formed along only one of the sidewalls of the first gate electrode 24. In some embodiments, a dielectric material layer 30 is present between the first and second device regions. In other embodiments, dielectric material layer 30 is omitted. In such an embodiment, the first and second shunting material pillars that are present along the facing sidewalls of the first and second gate structures 22, 24 can contact each other. Note that the various embodiments depicted in FIGS. 2A and 2B are applicable here for the structure show in FIG. 3.

The exemplary structure shown in FIG. 3 further illustrates that the first field effect transistor including the first gate structure 22 and the second field effect transistor including the second gate structure 24 are both located above a bottom dielectric isolation layer 12 that is present on a semiconductor substrate 10. In such an embodiment, both the first gate structure 22 and the second gate structure 24 can be in direct contact with the bottom dielectric isolation layer 12. In other embodiments (not shown, but readily derivable from the illustrated structure shown in FIG. 3), the bottom dielectric isolation layer 12 can be omitted and, in such embodiments, both the first gate structure 22 and the second gate structure 24 can be in direct contact with the semiconductor substrate 10.

As is further illustrated in FIG. 3, the structure further includes a first gate dielectric material layer 18 separating the first gate structure 22 from each first semiconductor channel material nanosheet 14NS of the plurality of first semiconductor channel material nanosheets, and a second gate dielectric material layer 20 separating the second gate structure 24 from each second semiconductor channel material nanosheet 16NS of the plurality of second semiconductor channel material nanosheets. Although not shown, the first field effect transistor would include first source/drain regions, and the second field effect transistor would include second source/drain regions. In FIG. 3, the first and second source/drain regions would present out from and into the plane of the drawing sheet containing FIG. 3.

Although not shown (but can be readily derived from FIG. 3), the present application contemplates at least one other first and/or second device regions located laterally adjacent to first and/or second device regions, in which the other first and/or second devices regions include field effect transistors that are devoid of a shunting material pillar.

Each of the semiconductor substrate 10, the bottom dielectric isolation layer 12, the first semiconductor channel material nanosheets 14NS, the first gate dielectric material layer 18, the first gate structure 22, the second semiconductor channel material nanosheets 16NS, the second gate dielectric material layer 20 and the second gate structure 24 of this illustrated embodiment is the same as that previously described for those components/elements shown in FIG. 1. The dielectric material layer 30 can include any dielectric material such as, for example, silicon dioxide, silicon nitride or an interlayer dielectric material. The dielectric material layer 30 can be omitted in some embodiments.

The first shunting material pillar 24A, and the second shunting material pillar 24B including shunting materials as mentioned above for the shunting material pillar 24 in the previous embodiment of the present application. In this embodiment, the first shunting material pillar 24A has a resistivity that is lower than a resistivity of the first gate structure 22 and the second shunting material pillar 24B has a resistivity that is lower than a resistivity of the second gate structure 24. The shunting material that provides the first shunting material pillar 24A can be compositionally the same as, or compositionally different from, the shunting material that provides the second shunting material pillar 24B.

In the present application, the first field effect transistor is a first conductivity type and the second field effect transistor is of second conductivity type, and the second conductivity type is of a different conductivity than the first conductivity type. In a first example, the first conductivity type is n-type, and the second conductivity type is p-type, and in a second example, the first conductivity type is p-type, and the second conductivity type is n-type. In yet other embodiments of the present application, the first field effect transistor is a first conductivity type and the second field effect transistor is of second conductivity type, and the second conductivity type is of a same conductivity as the first conductivity type. Thus, the present application contemplates a pFET laterally adjacent to an nFET, an nFET laterally adjacent to a pFET, an nFET laterally adjacent to another nFET, and a pFET laterally adjacent to another pFET.

The exemplary structure shown in FIG. 3 minus the first and shunting material pillars 26A, 26B can be formed utilizing well known nanosheet device processing techniques. So as not to obscure the method of forming the shunting material pillars, the processing details used in forming the nanosheet device shown in FIG. 3 will not be described herein. The first and second shunting material pillars 24A, 24B can be formed utilizing the technique mentioned above in forming the shunting material pillar 24 shown in FIG. 1. In some embodiments, a block mask can be inserted into the shunting material pillar formation process so as to form separate shunting material pillars in the respective device region.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first field effect transistor comprising a first gate structure, wherein the first gate structure has a first sidewall and a second sidewall opposite the first sidewall;
a second field effect transistor stacked vertically on top of the first field effect transistor and comprising a second gate structure, wherein the second gate structure has a first sidewall and a second sidewall opposite the first sidewall, and wherein the first sidewall of the second gate structure is vertically aligned with the first sidewall of the first gate structure and the second sidewall of the second gate structure is vertically aligned with the second sidewall of the first gate structure; and
a shunting material pillar located along at least one of the first sidewall of both the first gate structure and the second gate structure or the second sidewall of both the first gate structure and the second gate structure.

2. The semiconductor structure of claim 1, wherein the shunting material pillar is located along the first sidewall of both the first gate structure and the second gate structure, and along the second sidewall of both the first gate structure and the second gate structure.

3. The semiconductor structure of claim 1, wherein the shunting material pillar has a resistivity that is lower than a resistivity of both the first gate structure and the second gate structure.

4. The semiconductor structure of claim 3, wherein the shunting material pillar is composed of cobalt, tungsten, or ruthenium.

5. The semiconductor structure of claim 1, wherein the shunting material pillar has a length that is equal to a length of both the first gate structure and the second gate structure.

6. The semiconductor structure of claim 1, wherein the shunting material pillar has a length that greater than a length of both the first gate structure and the second gate structure.

7. The semiconductor structure of claim 1, wherein the first field effect transistor is a first conductivity type and the second field effect transistor is of second conductivity type, and the second conductivity type is of a different conductivity than the first conductivity type.

8. The semiconductor structure of claim 7, wherein the first conductivity type is n-type, and the second conductivity type is p-type.

9. The semiconductor structure of claim 7, wherein the first conductivity type is p-type, and the second conductivity type is n-type.

10. The semiconductor structure of claim 1, wherein the first field effect transistor is a first conductivity type and the second field effect transistor is of second conductivity type, and the second conductivity type is of a same conductivity as the first conductivity type.

11. The semiconductor structure of claim 1, wherein the first gate structure comprises one of an n-type work function metal or a p-type work function metal, and the second gate structure comprises the other of the n-type work function metal or the p-type work function metal.

12. The semiconductor structure of claim 1, wherein the first field effect transistor is located above a bottom dielectric isolation layer that is present on a semiconductor substrate.

13. The semiconductor structure of claim 1, wherein the first field effect transistor is located in a first device region, and the second field effect transistor is located in a second device region, wherein the first device region is spaced apart from the second device region by a device separating dielectric material layer.

14. The semiconductor structure of claim 1, wherein the first gate structure wraps around each first semiconductor channel material nanosheet of a plurality of first semiconductor channel material nanosheets, and the second gate structure wraps around each second semiconductor channel material nanosheet of a plurality of second semiconductor channel material nanosheets.

15. The semiconductor structure of claim 14, further comprising a first gate dielectric material layer separating the first gate structure from each first semiconductor channel material nanosheet of the plurality of first semiconductor channel material nanosheets, and a second gate dielectric material layer separating the second gate structure from each second semiconductor channel material nanosheet of the plurality of second semiconductor channel material nanosheets.

16. The semiconductor structure of claim 1, further comprising at least one other stacked field effect transistor device located laterally adjacent to first field effect transistor and the second field effect transistor, wherein the at least one other stacked field effect transistor device is devoid of a shunting material pillar.

17. A semiconductor structure comprising:
a first field effect transistor located in a first device region and comprising a first gate structure;
a second field effect transistor located in a second device region that is laterally adjacent to the first device region and comprising a second gate structure; and
a first shunting material pillar located along at least one sidewall of the first gate structure;
a second shunting material pillar located along at least one sidewall of the second gate structure.

18. The semiconductor structure of claim 17, wherein the first shunting material pillar has a resistivity that is lower than a resistivity of the first gate structure and second shunting material pillar has a resistivity that is lower than a resistivity of the second gate structure.

19. The semiconductor structure of claim 17, wherein the first gate structure wraps around each first semiconductor channel material nanosheet of a plurality of first semiconductor channel material nanosheets, and the second gate structure wraps around each second semiconductor channel material nanosheet of a plurality of second semiconductor channel material nanosheets.

20. The semiconductor structure of claim 19, further comprising a first gate dielectric material layer separating the first gate structure from each first semiconductor channel material nanosheets of the plurality of first semiconductor channel material nanosheets, and a second gate dielectric material layer separating the second gate structure from each second semiconductor channel material nanosheets of the plurality of second semiconductor channel material nanosheets.
